(19) United States
(12) Patent Application Publication
(10) Pub. No.: US 2003/0049545 A1
(43) Pub. Date: Mar. 13, 2003

(54) Methods for manufacturing reticles and reticle blanks exhibiting reduced warp and resist stress for use in charged-particle-beam microlithography

(75) Inventor: Norihiro Katakura, Kawasaki-shi (JP)

Correspondence Address: KLARQUIST SPARKMAN, LLP, One World Trade Center, Suite 1600, 121 S.W. Salmon Street, Portland, OR, 97204-2988, US

(73) Assignee: Nikon Corporation

(21) Appl. No.: 10/236,779

(22) Filed: Sep. 6, 2002

(30) Foreign Application Priority Data
Sep. 7, 2001 (JP) 2001-271958
Jun. 17, 2002 (JP) 2002-175280

(51) Int. Cl. G03F 9/00; G03C 5/00; C25B 9/00; C25B 11/00; C25B 13/00; C23C 14/00; B32B 9/00; B32B 17/06

(52) U.S. Cl. 430/5; 430/296; 428/428; 204/298.31

(57) ABSTRACT

Reticle blanks, and divided reticles made therefrom, are disclosed for use in charged-particle-beam microlithography. The subject reticle blanks and reticles exhibit substantially reduced warp and resist stress, and hence substantially reduced positional distortion, compared to conventional reticles and reticle blanks. A reticle blank includes a silicon membrane supported on a grillage of struts formed from a thick silicon support substrate. The support substrate is made and worked separately to form the grillage of support struts and the membrane. A separate silicon-on-insulator (SOI) wafer is formed, including a silicon “active” layer, a buried oxide (BOX) layer, and a support wafer. The surface of the active layer is bonded to the surface of the support substrate, and the support wafer and BOX layer are removed to complete fabrication of the reticle blank. The support substrate has a thickness of at least 1 mm.

### FIELD

This disclosure pertains to microlithography, which is a key technique used in the fabrication of micro-electronic devices such as semiconductor integrated circuits, displays, and the like. More specifically, the disclosure pertains to microlithography performed using a charged particle beam such as an electron beam or ion beam, and to pattern-defining reticles used in charged-particle-beam (CPB) microlithography. Even more specifically, the disclosure pertains to methods for manufacturing, from a “reticle blank,” a CPB microlithography reticle that exhibits very little warping or consequential distortion caused by residual stress.

### BACKGROUND

In recent years, as micro-electronic devices have become more highly integrated, the need has become acute for microlithography systems capable of achieving finer pattern resolution than conventional optical microlithography. To meet this need, several types of “next generation lithography” (NGL) systems currently are under intensive development. One type of NGL system utilizes a charged particle beam (e.g., electron beam or ion beam) as a lithographic energy beam. Another type utilizes X-rays (notably “soft” X-rays or “extreme UV” light).

Among these NGL systems, electron-beam systems have been developed that are capable of producing and utilizing a beam diameter of a few nanometers, which facilitates resolution of a pattern having pattern elements with a line width of 0.1 μm or finer. These systems do not utilize a reticle, and form a pattern on a lithographic substrate by “direct writing” of the pattern element-by-element. A disadvantage of these direct-writing systems is their extremely low throughput. Also, as the pattern is made finer, it must be drawn with a correspondingly more constricted beam, which causes corresponding increases in the time required for “drawing” the pattern on the substrate. Consequently, direct-writing systems are impractical for large-scale production of micro-electronic devices.

In an effort to improve throughput substantially, CPB microlithography systems have been developed in which the pattern, as defined on a reticle, is divided into small regions, termed subfields, that define respective portions of the overall pattern. The subfields are exposed individually in respective “shots” in a sequential manner onto corresponding locations on the substrate such that the subfield images are “stitched” together in a contiguous manner. Each subfield as exposed onto the substrate has dimensions of, for example, several hundred micrometers square. These reticles are termed “divided” reticles.

An elevational section of a portion of a divided reticle is shown in FIG. 6(a), and a corresponding perspective view is shown in FIG. 6(b). Generally, two main types of divided reticles are used for CPB microlithography. A first type is a so-called “stencil” reticle in which the pattern elements are defined as corresponding apertures (not shown in the figures) in a CPB-transmissive membrane 1 (usually made of silicon) having a thickness of approximately 2 μm. A second type is a so-called “continuous-membrane” reticle in which the pattern elements are defined as respective voids in a heavy-metal layer formed on a continuous silicon membrane 1 having a thickness of approximately 0.1 μm.

With either type of reticle, the area that can be exposed in a single shot is approximately 250 μm square on the substrate, corresponding to an area of approximately 1 mm square on the reticle, assuming a demagnification factor of ¼. To define an entire pattern for transfer to a substrate, a large reticle is required that consists of a large number (e.g., thousands) of subfields. In view of the thinness of the reticle membrane in either type of divided reticle, the membranes larger than an individual subfield are not self-supporting. Accordingly, the reticles include a “grillage” (also called a “lattice” in the art) of supportive struts 2 that provide the reticle with considerable structural rigidity and stability. The thickness of each strut 2 (in the Z-direction) is much greater than the thickness of the reticle membrane 1. For example, in the case of an 8-inch diameter reticle, the struts have a thickness of about 725 μm.

A divided reticle such a shown in FIGS. 6(a)-6(b) conventionally is made by a method that begins with preparing a (100)-plane silicon wafer of which one major surface is doped with boron (at a concentration of 1×10²⁰ atoms/cm³). A resist pattern, corresponding to the grillage of struts, is applied to the opposite major surface, followed by formation of a layer of silicon nitride in regions corresponding to intended locations of the struts. Areas of the surface unprotected by the silicon nitride are wet-etched, using an aqueous solution of potassium hydroxide, depthwise into the thickness dimension of the silicon to the doped layer. The doped layer slows the etching rate and thus serves as an etching stop. The remaining thin layer of doped silicon, supported by the support struts, is destined to become the reticle membrane. Next, the surface of the membrane is coated with a resist and patterned according to the intended pattern to be defined on the reticle. The patterning of the resist normally is performed using an electron-beam reticle-drawing apparatus. The resist is developed and used in an etching step to form the pattern in or on the membrane.

In the conventional method described above, since wet-etching is anisotropic with respect to certain silicon crystal planes, the struts are formed having an angle of 54.74° relative to the membrane. Having to accommodate such sloped sides results in the reticle (used to define a chip pattern) having to be extremely large. To reduce the reticle size, a reticle-fabrication method involving dry-etching for forming the struts has been proposed. Dry etching is capable of forming struts having walls oriented at substantially 90° relative to the membrane. The resulting slimmer struts allow the reticle to be reduced in size correspondingly.

One conventional method for making a reticle having “vertical-wall” struts is performed using a boron-doped silicon wafer. Respective steps of the method are shown in FIGS. 7(a)-7(c). First, as is shown in FIG. 7(a), the surface of a silicon wafer 4 is doped with boron to form a boron-doped layer 3. Next, as shown in FIG. 7(b), the vertical-wall struts 2 are formed by patterning the opposite surface of the wafer with a layer of silicon oxide 5 and dry-etching into the thickness dimension of the wafer 4 from the opposite surface. Etching is allowed to progress to a depth that is several tens of micrometers less than the desired “height” of the struts. Next, as shown in FIG. 7(c), wet etching is used only for removing the thin layer of residual silicon up to the boron-doped layer 3 (serving as an etch-stop layer). The remaining boron-doped layer 3 is destined to become the reticle membrane having a desired thickness. Finally, the silicon oxide layer 5 is removed.

A method that simplifies the method of FIGS. 7(a)-7(c) even further begins with a SOI (silicon-on-insulator) wafer. An elevational section of a portion of such a wafer is shown in FIG. 8. The depicted SOI wafer includes a silicon buried-oxide layer (“BOX” layer) 7 formed on the surface of a silicon-support substrate 8. A thin-film silicon layer (“active” layer) 6 is formed on the BOX layer 7. The resulting intermediate BOX layer 7 can be used as an etch-stop layer for a subsequent dry-etching step. By patterning the opposite surface of the support substrate 8 as described above, followed by dry-etching the exposed regions of the support substrate 8, a reticle blank can be produced having “vertical” struts (i.e., struts that are perpendicular to the plane of the reticle membrane). Each strut has a width of several hundred micrometers.

FIGS. 9(a)-9(c) are elevational sections showing the results of respective steps in a conventional method for manufacturing a reticle blank from an SOI wafer. First, as shown in FIG. 9(a), an SOI wafer is constructed that includes an active layer 6, a BOX layer 7, and a support substrate 8. Next, as shown in FIG. 9(b), a resist or silicon oxide layer 9 is formed on the opposite surface of the support substrate 8. As shown in FIG. 9(c), the resist or silicon oxide layer 9 is patterned to produce “protected” regions in which support struts 8a, 8b, 8c are to be formed. Using the patterned layer 9 as a mask, the support substrate 8 is dry-etched, with the BOX layer 7 being used as an etch-stop. After dry-etching, the BOX layer 7 is removed by wet etching, and the residual portions of the patterned layer 9 are stripped away. Thus, a reticle blank is produced that has perpendicular support struts 8a, 8b, 8c. The struts 8b each have a width of several hundred micrometers.

In all of the conventional methods summarized above, etching must be performed to a depth that corresponds to the thickness of the support substrate (silicon wafer). For example, etching must be performed to a depth of 300 μm or greater whenever the reticle blank is made from a 3-inch diameter wafer, and to a depth of 700 μm or greater whenever the reticle blank is made from an 8-inch diameter wafer.

Dry-etching to such depths usually must be performed using side-wall protection. Side-wall protection facilitates the formation of perpendicular walls by performing the etching in the presence of a polymer-forming gas. In the dry-etching environment, the gas reacts to form a polymer that coats the vertical walls of the etched voids. The polymer coating prevents dry-etching from progressing in the lateral direction.

An exemplary reticle blank, for use in fabricating a reticle for CPB microlithography, formed from an 8-inch diameter wafer is shown in FIG. 10. The reticle blank 10 includes two structurally worked regions (membrane areas) 11 each configured with a respective grillage of support struts and each having dimensions of 132 mm×55 mm. The regions 11 are arranged side-by-side on the reticle blank 10.

Unfortunately, reticle blanks manufactured from a SOI wafer using conventional methods as summarized above suffer from the following problems:

First, the support substrate 8 tends to exhibit an extremely large amount of warping compared to glass reticles as used in optical microlithography. Consequently, the support struts 8a-8c of a reticle made from such a reticle blank exhibit substantial distortion when chucked to a reticle stage in a CPB microlithography apparatus.

Second, to perform the working that results in formation of the support struts on the support substrate 8, it is necessary first to coat the respective surface of the support substrate 8 with a resist film. Also, after forming the reticle blank, a reticle pattern is formed on or in the active layer 6 by a process that involves application of a resist to the surface of the active layer. These resists impart “resist stress” to the reticle that causes positional distortion of the reticle blank and/or reticle formed therefrom.

### SUMMARY

In view of the shortcomings of the prior art as summarized above, the present invention provides, inter alia, reticle blanks and reticles for use in charged-particle-beam (CPB) microlithography, and methods for manufacturing such reticle blanks and reticles, in which warping is reduced substantially compared to conventional reticle blanks, reticles, and methods. The subject reticle blanks and reticles exhibit substantially reduced positional distortion caused by resist stress.

According to a first aspect of the invention, reticle blanks are provided for making a divided reticle used in charged-particle-beam microlithography. An embodiment of such a reticle blank comprises a membrane and a support substrate. The support substrate, having a thickness of at least 1 mm, defines a “grillage” of support struts that support the membrane and divide the membrane into subfields. Desirably, the support substrate is silicon, with a thickness of 1 to 5 mm. The membrane can be silicon that has been doped with an impurity (e.g., phosphorus) to regulate stress in the membrane.

According to another aspect of the invention, reticles are provided for use in charged-particle-beam microlithography. An embodiment of such a reticle comprises a reticle membrane and a support substrate. The reticle membrane defines elements of a pattern. The support substrate (having a thickness of at least 1 mm) defines a grillage of support struts that support the membrane and divide the membrane into subfields. Desirably, the support substrate is silicon, with a thickness of 1 to 5 mm. The membrane can be silicon that has been doped with an impurity (e.g., phosphorus) to regulate stress in the membrane.

According to another aspect of the invention, methods are provided for manufacturing a reticle blank for making a divided reticle used in charged-particle-beam microlithography. An embodiment of such a method comprises the step of preparing a silicon support substrate having a thickness of at least 1 mm. In a subsequent step the support substrate is worked to form therein a grillage of support struts defining voids in the support substrate corresponding to locations of respective subfields in the reticle blank. In a subsequent step an SOI wafer is constructed that comprises an active layer, a buried oxide (BOX) layer, and a support-wafer layer. In a subsequent step a major surface of the active layer of the SOI wafer is bonded to a major surface of the support substrate. In a subsequent step the support-wafer layer and the buried oxide layer are removed to form the reticle blank having a membrane, made from the active layer, divided into subfields supported by the grillage of support struts.

Another method embodiment comprises the step of preparing a silicon support substrate having a thickness of at least 1 mm. In a subsequent step the support substrate is worked to form therein a grillage of support struts defining voids in the support substrate corresponding to locations of respective subfields in the reticle blank. In a subsequent step an SOI wafer is constructed comprising an active layer, a buried oxide layer, and a support-wafer layer. In a subsequent step an oxide film is formed on a major surface of the active layer. In a subsequent step the oxide film on the active layer is bonded to a major surface of the support substrate. In a subsequent step, the support-wafer layer and the buried oxide layer are removed to form the reticle blank having a membrane, made from the active layer, divided into subfields supported by the grillage of support struts.

Another method embodiment comprises the step of preparing a silicon support substrate having a thickness of at least 1 mm. In a subsequent step the support substrate is worked to form therein a grillage of support struts defining voids in the support substrate corresponding to locations of respective subfields in the reticle blank. In a subsequent step an oxide film is formed on a major surface of the support substrate. In a subsequent step an SOI wafer is constructed comprising an active layer, a buried oxide layer, and a support-wafer layer. In a subsequent step a major surface of the active layer is bonded to the oxide film. In a subsequent step the support-wafer layer and the buried oxide layer are removed to form the reticle blank having a membrane, made from the active layer, divided into subfields supported by the grillage of support struts.

In yet another method embodiment, a silicon support substrate is prepared having a thickness of at least 1 mm. The support substrate is worked to form therein a grillage of support struts defining voids in the support substrate corresponding to locations of respective subfields in the reticle blank. A bonding substrate is prepared comprising a thin-film silicon layer. Finally, a major surface of the thin-film silicon layer is bonded to a major surface of the support substrate.

In any of the method embodiments described above, the silicon support substrate can be prepared having a thickness desirably in the range of 1 to 5 mm. The method further can comprise the step, after removing the buried oxide layer, of introducing an impurity into the active layer for use in stress reduction of the active layer. The method further can comprise the step, between the step of preparing the SOI wafer and the bonding step, of introducing an impurity into the active layer for use in stress reduction of the active layer. The working step can be performed by anisotropic working. For example, the working step can be performed by a technique selected from the group consisting of ultrasonic working, plasma-discharge machining, or laser machining.

Since relatively thick (significantly thicker than conventionally) silicon is used to form the support substrate that provides support to the membrane, warping is reduced substantially compared to conventional reticle blanks and reticles (in which the support substrate has a maximum thickness of approximately 0.7 mm). As a result, distortion arising from chucking of the reticle onto a reticle stage in a CPB microlithography apparatus, as well as positional distortion of the reticle caused by resist stress, is reduced substantially.

The foregoing and additional features and advantages of the invention will be more readily apparent from the following detailed description, which proceeds with reference to the accompanying drawings.

### BRIEF DESCRIPTION OF THE DRAWINGS

FIG. 1(a) is a plan view of an embodiment of a reticle blank suitable for use in fabricating a divided reticle for charged-particle-beam (CPB) microlithography.

FIG. 1(b) is an elevational section along the line 1b-1b in FIG. 1(a).

FIG. 2(a) is a plan view of the thick silicon support substrate used in the fabrication of the reticle blank shown in FIG. 1(a).

FIG. 2(b) is an elevational section along the line 2b-2b in FIG. 2(a).

FIG. 3(a) is an elevational section of the silicon support substrate of FIGS. 2(a)-2(b) after having worked into a structure having two regions including respective grillages of support struts.

FIG. 3(b) is an elevational section of a portion of an SOI wafer used in fabricating a reticle blank from the support substrate shown in FIG. 3(a).

FIG. 4 is an elevational section of the support substrate of FIG. 3(a) bonded to the SOI wafer of FIG. 3(b).

FIG. 5 is an elevational section of the structure of FIG. 4 after removing the BOX layer (buried silicon oxide layer) and support-wafer layer.

FIG. 6(a) is an elevational section of a portion of a conventional divided reticle blank.

FIG. 6(b) is an oblique view of the portion of a reticle blank shown in FIG. 6(a).

FIGS. 7(a)-7(c) are elevational sections illustrating the results of respective steps in a method for manufacturing a conventional divided reticle blank.

FIG. 8 is an elevational section of a conventional SOI (silicon-on-insulator) wafer.

FIGS. 9(a)-9(c) are elevational sections illustrating the results of respective steps in a method for manufacturing a conventional divided reticle blank from an SOI wafer.

FIG. 10 is a plan view of a conventional CPB microlithography reticle made from an 8-inch diameter wafer.

### DETAILED DESCRIPTION

The invention is described below in the context of representative embodiments that are not intended to be limiting in any way.

First Representative Embodiment

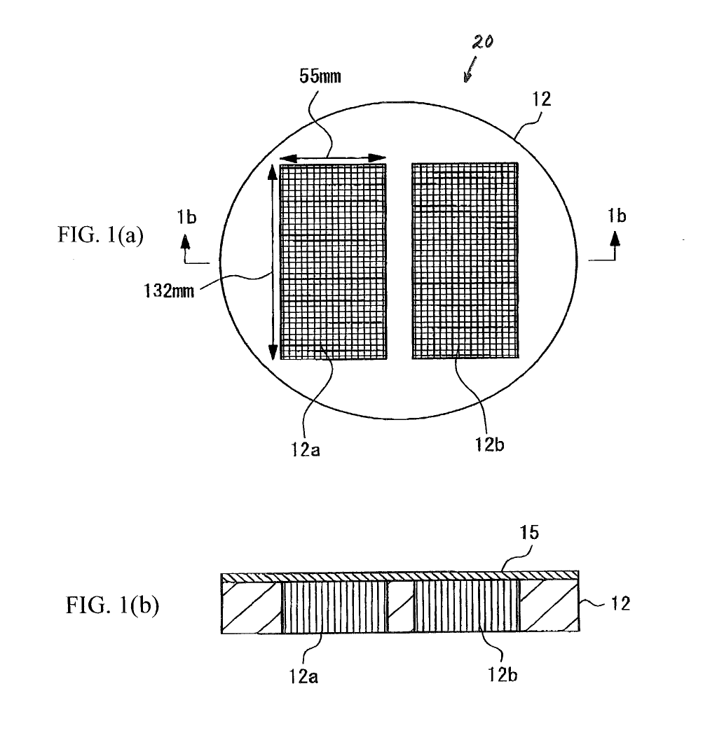

A first representative embodiment of a reticle blank is shown in FIGS. 1(a)-1(b), wherein FIG. 1(a) is a plan view, and FIG. 1(b) is an elevational section along the line 1b-1b in FIG. 1(a). As shown in FIG. 1(a), the reticle blank is made from a thick silicon support substrate 12 polished to a flatness of 5 μm or better. The support substrate 12 has a diameter of 8 inches and a thickness of 5 mm. Two “structurally worked” regions 12a, 12b, respectively, are defined on the support substrate 12. Each structurally worked region 12a, 12b has respective dimensions of 132 mm×55 mm and includes a “grillage” of support struts formed from the bulk silicon of the support substrate 12.

Turning to FIG. 1(b), the reticle blank includes a thin-film silicon layer (“active” layer) 15 having a thickness of approximately 2 μm. The active layer 15 serves as a membrane on which the reticle pattern will be formed. As discussed below, the active layer 15 is formed as a separate unit (with several additional layers) that is adhered to the surface of the support substrate 12 after the support substrate 12 has been worked into a structure including the support struts. As discussed below, impurities can be introduced into the active layer 15 for the purpose of regulating stress in the active layer.

In the resulting structure, as shown in FIGS. 1(a)-1(b), each structurally worked region 12a, 12b of the reticle blank 20 comprises a grillage of support struts that support a membrane. The support struts divide the membrane in each region 12a, 12b into a large number of subfields. Each subfield has a respective membrane portion having dimensions on the reticle blank of, by way of example, approximately 1 mm square. (When projected onto a lithographic substrate at a demagnification ratio of ¼, a subfield having such dimensions would produce a subfield image having dimensions of approximately 250 μm square.)

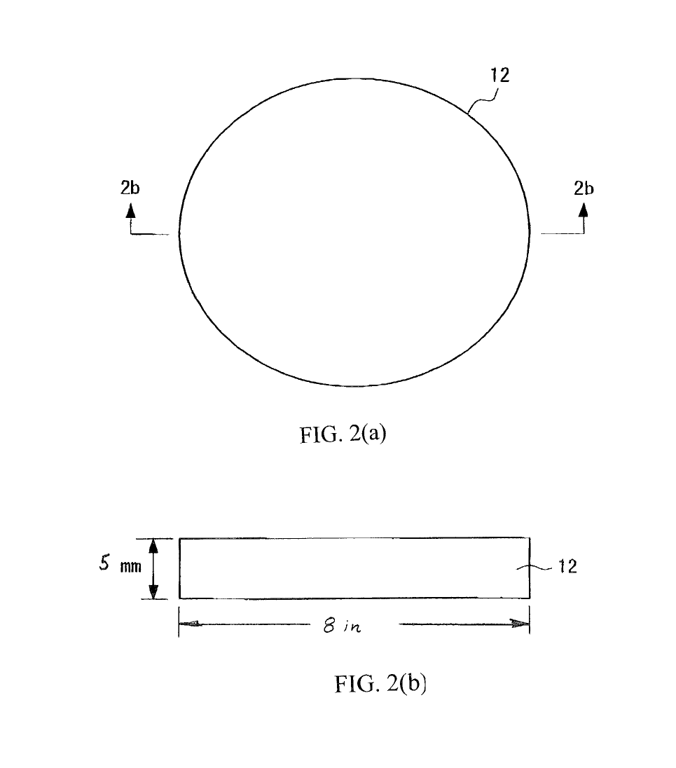

The reticle blank 20 is manufactured by a method as diagrammed in FIGS. 2(a)-2(b), 3(a)-3(b), and 4-5. FIG. 2(a) is a plan view of the thick silicon support substrate 12, and FIG. 2(b) is an elevational section along the line 2b-2b in FIG. 2(a). Thus, FIGS. 2(a)-2(b) depict the fabrication of a thick silicon support substrate 12 having a diameter of 8 inches, a thickness of 5 mm, and a flatness of 5 μm or better.

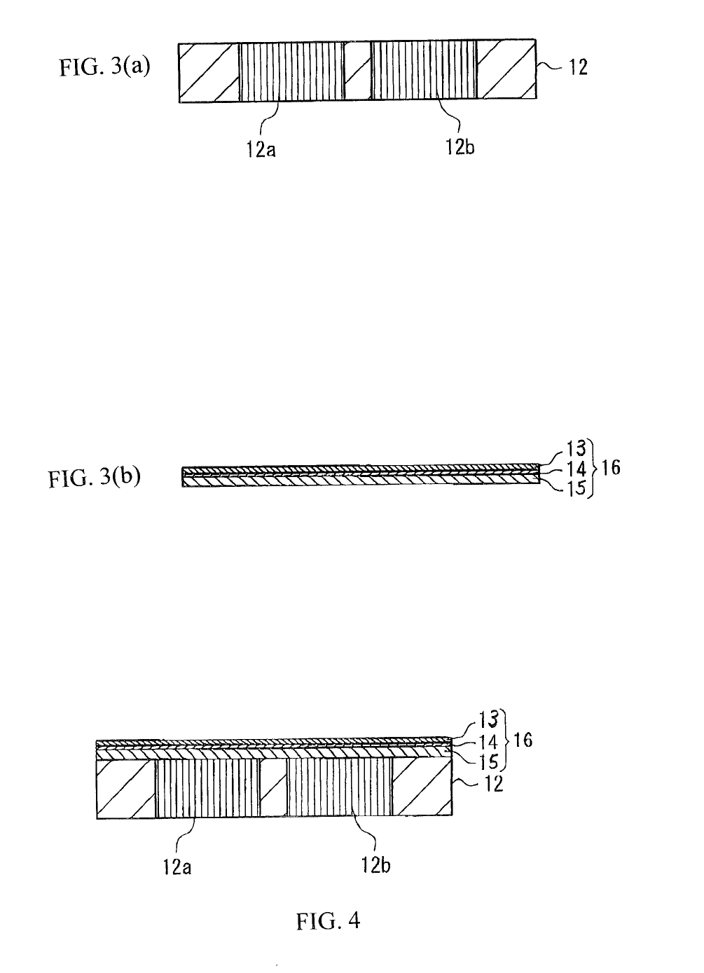

Turning now to FIG. 3(a), the support substrate 12 is worked ultrasonically to form the grillage of support struts in each of the regions 12a, 12b. Next, the support substrate 12 is cleaned. In a separate step, an SOI wafer 16 (having a diameter of 8 inches) is prepared, having a configuration as shown in FIG. 3(b). The SOI wafer 16 comprises silicon support wafer 13, a silicon oxide layer (“BOX” layer) 14 on the surface of the support wafer 13, and a thin-film silicon layer (“active” layer) 15 on the surface of the BOX layer 14. The active layer 15 has a thickness of approximately 2 μm.

Next, as shown in FIG. 4, the surface of the active layer 15 is bonded (e.g., adhered), at room temperature, to the surface of the support substrate 12, then annealed at 1100° C. These conditions result in chemical bonding of the SOI wafer 16 to the support substrate 12. Before performing this adhesion step, it is desirable to form an oxide film layer (having a thickness of approximately 100 nm) on either the surface of the active layer 15 of the SOI wafer 16 or the surface of the support substrate 12. This adhesion step is similar to a corresponding step used in the fabrication of the SOI wafer.

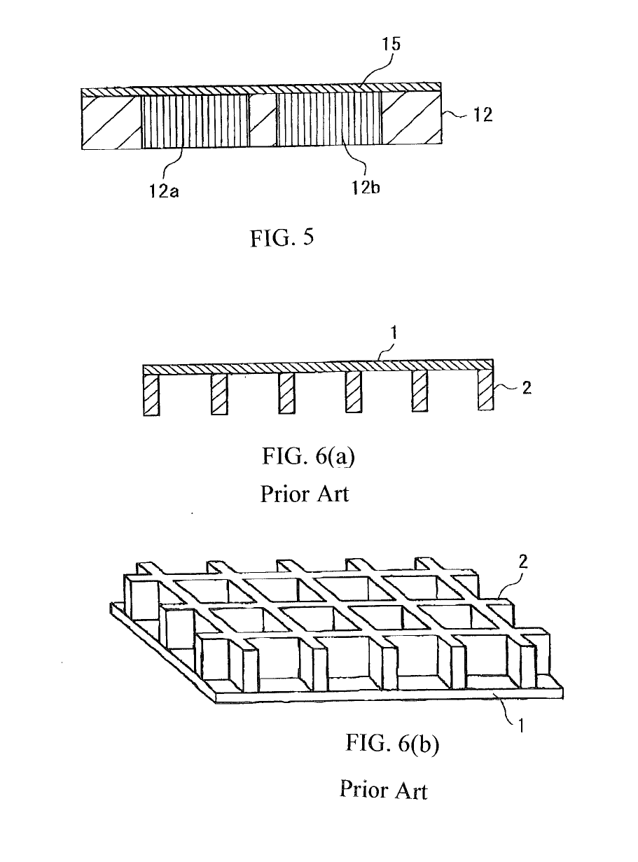

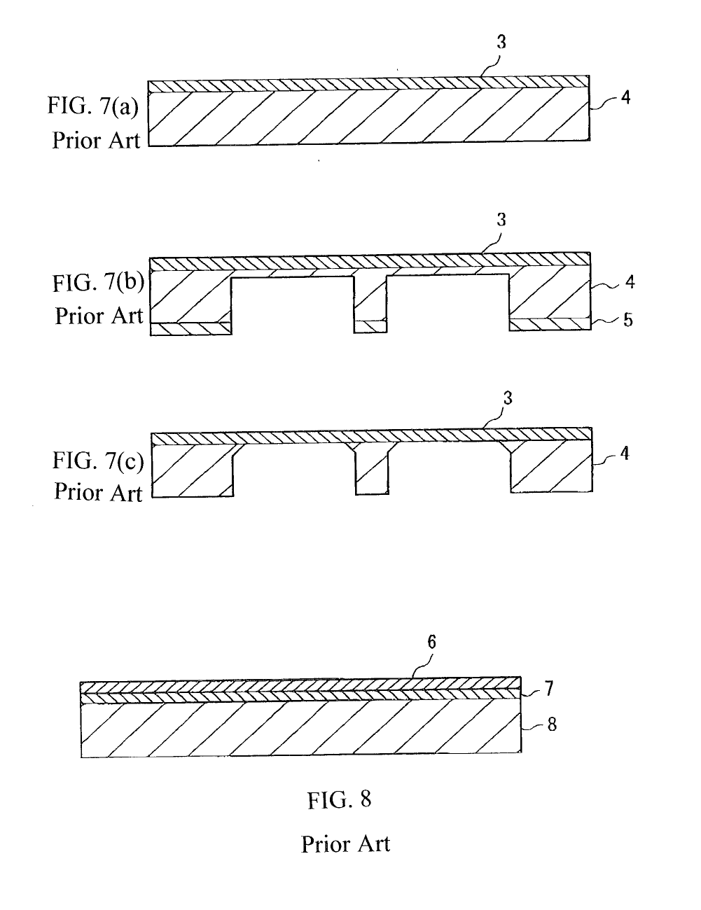

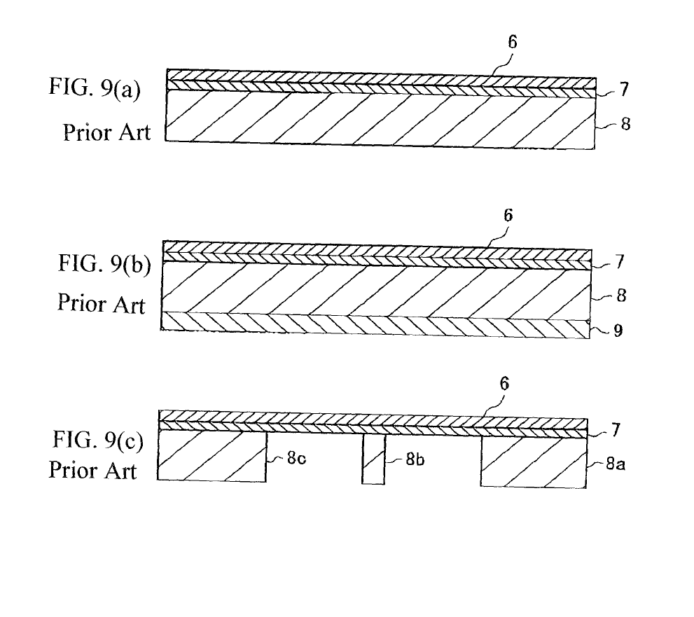

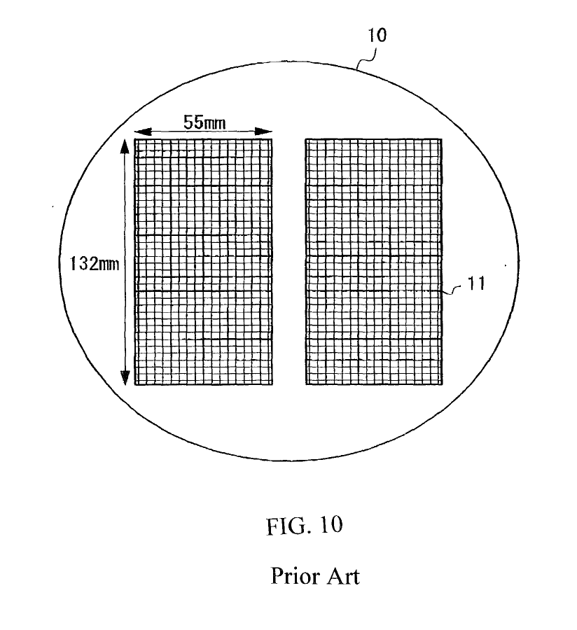

Afterward, as shown in FIG. 5, the support wafer 13 is removed by wet-etching using potassium hydroxide solution. Next, the BOX layer 14 is removed by wet-etching using a mixed solution of hydrofluoric acid and ammonium fluoride. This etching solution has a sufficient etching selectivity (i.e., sufficient difference in etching rate) between the BOX layer 14 and the active layer 15 so that absolutely no etching of the active layer 15 (destined to become the reticle membrane) occurs. In situations in which an oxide film layer was formed just before performing the adhesion step, the resulting oxide film layer at the interface between the support substrate 12 and the active layer 15 also is removed by wet-etching.

Next, the active layer 15 is doped with a phosphorus impurity by thermal diffusion using a thermal-diffusion apparatus. The dopant serves to regulate stress in the active layer 15 when the active layer is converted into a membrane of the reticle blank. The doped phosphorus concentration for this purpose is, for example, approximately 1×10¹⁸ atoms/cm³.

Thus, a reticle blank 20 (FIG. 1(a)) for use in fabricating a CPB-microlithography reticle is manufactured.

The CPB-microlithography reticle is fabricated by forming a reticle pattern (not shown in the figures) in or on the membrane 15. Pattern elements are formed “in” the membrane by forming respective apertures in the membrane 15 (thereby forming a stencil reticle). Pattern elements are formed “on” the membrane by forming a layer of a suitable heavy metal on the membrane 15, followed by patterning the heavy metal layer according to the arrangement and configurations of the pattern elements (thereby forming a continuous membrane reticle). Patterning the membrane in either manner is performed lithographically.

In the embodiment discussed above, since the support substrate 12 supporting the membrane has a thickness of, e.g., approximately 5 mm, warping of the reticle blank or membrane is reduced substantially compared to conventional reticle blanks in which the support substrate has a thickness of approximately 725 μm. As a result, reticle distortion caused by the chucking of the reticle onto a reticle stage of a CPB microlithography apparatus, as well as positional distortion caused by resist stress, are reduced substantially.

Various modifications can be made to the embodiment discussed above. For example, in the discussed embodiment a silicon support substrate having a thickness of 5 mm was used. Alternatively, another thickness can be used so long as the thickness is greater than 1 mm (see second representative embodiment). By way of another example, in the discussed embodiment ultrasonic working was used to form the grillage of support struts in the support substrate 12. Alternatively, any of various other techniques can be used to work the support substrate, such as, e.g., plasma-discharge machining or laser machining. By way of another example, in the discussed embodiment, the SOI wafer 16 and the support substrate 12 were adhered together by direct bonding. Alternatively, another technique can be used such as anodic bonding. By way of another example, in the discussed embodiment the support wafer 13 and BOX layer 14 were removed, after the bonding step, by wetetching. Alternatively, any of various other layer-removal techniques can be used such as, for example, grinding/polishing or dry-etching. By way of another example, in the discussed embodiment the active layer 15 was doped with phosphorus by thermal diffusion. Alternatively, dopant can be introduced into the active layer by ion injection. By way of another example, in the discussed embodiment the active layer 15 was doped with phosphorus. Alternatively, other dopants can be used, such as boron, so long as the dopant serves to regulating stress in the active layer. By way of another example, in the discussed embodiment the dopant impurity was introduced (for the purpose of stress regulation) after the SOI wafer 16 and support substrate 12 were bonded together. Alternatively, the impurity can be introduced into the SOI wafer before the bonding step.

Second Representative Embodiment

This embodiment is described using the same respective figures used in the description of the first representative embodiment. Specifically, in this embodiment, the subject reticle blank comprises a thick silicon support substrate 12 that, as fabricated, has a diameter of 8 inches and a flatness of 5 μm or better. As shown in FIG. 1(a), each of the two structurally worked regions 12a, 12b formed in the support substrate 12 has a rectangular shape with a surface dimensions of 132 mm ×55 mm.

In this embodiment, the support substrate 12 is silicon, with a thickness ranging from 1 mm to 5 mm. Alternatively, the support substrate 12 can have any of various other thicknesses. The range of 1 mm to 5 mm is established in view of the magnitude of intrinsic warping of the reticle blank, the rigidity of the reticle blank, and the ease with which the grillage of support struts could be formed in the support substrate 12. In concrete terms, several silicon wafers each having a diameter of 8 inches but with different respective thicknesses were prepared for use as support substrates. Support struts each having a width of 0.17 mm were formed in each support substrate, with intervening membranes having a thickness of 2 μm. The support substrates were assembled into respective reticle blanks, and the warp of each reticle blank was measured using an interference-type coordinate-measuring device. Also, after each reticle blank was coated with a resist, the positional distortion of the reticle blanks was measured.

The results of these measurements revealed that, whenever the thickness of the silicon support substrate was greater than 1 mm, warp and positional distortion were reduced to respective levels having no significant effect on electron-beam exposure performed using the respective reticles (e.g., warp of 5 μm or less, and positional distortion of 10 nm or less). It also was found that, whenever the thickness of the support substrate was greater than 5 mm, working of the support substrate to form support struts having uniform width became difficult. Based on these results, by configuring the silicon support substrate with a thickness within the range of 1 mm to 5 mm, warping of the reticle blank and positional distortion caused by the resist on the membrane are substantially eliminated, and uniform-width support struts are formed.

The reticle blank 20 is manufactured by a method as diagrammed in FIGS. 2(a)-2(b), 3(a)-3(b), and 4-5. FIG. 2(a) is a plan view of the thick silicon support substrate, and FIG. 2(b) is an elevational section along the line 2b-2b in FIG. 2(a). Thus, FIGS. 2(a)-2(b) depict the fabrication of a thick silicon support substrate 12 having a diameter of 8 inches, a thickness of 5 mm, and a flatness of 5 μm or better.

Turning now to FIG. 3(a), the support substrate 12 is worked ultrasonically to form the grillage of support struts in each of the regions 12a, 12b. Next, the support substrate 12 is cleaned. In a separate step, an SOI wafer 16 (having a diameter of 8 inches) is prepared, having a configuration as shown in FIG. 3(b). The SOI wafer 16 comprises silicon support wafer 13, a silicon oxide layer (“BOX” layer) 14 on the surface of the support wafer 13, and a thin-film silicon layer (“active” layer) 15 on the surface of the BOX layer 14. The active layer 15 has a thickness of approximately 2 μm.

Although an SOI wafer is used as a “bonding substrate” in this embodiment, this is not intended to be limiting. Any of various other bonding substrates can be used, so long as it has a thin-film silicon layer.

Next, as shown in FIG. 4, the surface of the active layer 15 is bonded (e.g., adhered), at room temperature, to the surface of the support substrate 12, then annealed at 1100° C. These conditions result in chemical bonding of the SOI wafer 16 to the support substrate 12. Before performing this adhesion step, it is desirable to form an oxide film layer (having a thickness of approximately 100 nm) on either the surface of the active layer 15 of the SOI wafer 16 or the surface of the support substrate 12. This adhesion step is similar to a corresponding step used in the fabrication of the SOI wafer.

Afterward, as shown in FIG. 5, the support wafer 13 is removed by wet-etching using potassium hydroxide solution. Next, the BOX layer 14 is removed by wet-etching using a mixed solution of hydrofluoric acid and ammonium fluoride. This etching solution has a sufficient etching selectivity (i.e., sufficient difference in etching rate) between the BOX layer 14 and the active layer 15 so that absolutely no etching of the active layer 15 (destined to become the reticle membrane) occurs. In situations in which an oxide film layer was formed just before performing the adhesion step, the resulting oxide film layer at the interface between the support substrate 12 and the active layer 15 also is removed by wet-etching.

Next, the active layer 15 is doped with a phosphorus impurity by thermal diffusion using a thermal-diffusion apparatus. The dopant serves to regulate stress in the active layer 15 when the active layer is converted into a membrane of the reticle blank. The doped phosphorus concentration for this purpose is, for example, approximately 1×10¹⁸ atoms/cm³.

Thus, a reticle blank 20 (FIG. 1(a)) for use in fabricating a CPB-microlithography reticle is manufactured.

The CPB-microlithography reticle is fabricated by forming a reticle pattern (not shown in the figures) in or on the membrane 15. Pattern elements are formed “in” the membrane by forming respective apertures in the membrane 15 (thereby forming a stencil reticle). Pattern elements are formed “on” the membrane by forming a layer of a suitable heavy metal on the membrane 15, followed by patterning the heavy metal layer according to the arrangement and configurations of the pattern elements (thereby forming a continuous membrane reticle). Patterning the membrane in either manner is performed lithographically.

In this embodiment, since a silicon support substrate 12 having a thickness of, e.g., approximately 5 mm is used for supporting the membrane, warping is reduced substantially compared to conventional reticle blanks in which an 8-in diameter support substrate has a thickness of approximately 725 μm (0.725 mm). This decreased warp correspondingly reduces distortion caused by chucking the reticle onto a reticle stage as well as positional distortion caused by application of resist to the membrane.

Various modifications can be made to this embodiment. For example, in the discussed embodiment a silicon support substrate having a thickness of 1-5 mm was used. Alternatively, another range of thickness can be used so long as the minimum thickness is about 1 mm, in contrast to the maximum thickness of 0.7 mm of the support substrate in conventional reticle blanks. By way of another example, in the discussed embodiment ultrasonic working was used to form the grillage of support struts in the support substrate 12. Alternatively, any of various other techniques can be used to work the support substrate, such as, e.g., plasma-discharge machining or laser machining. These techniques are anisotropic and produce silicon support struts having uniform-width “vertical” walls. By way of another example, in the discussed embodiment, the SOI wafer 16 and the support substrate 12 were adhered together by direct bonding. Alternatively, another technique can be used such as anodic bonding. By way of another example, in the discussed embodiment the support wafer 13 and BOX layer 14 were removed, after the bonding step, by wet-etching. Alternatively, any of various other layer-removal techniques can be used such as, for example, grinding/polishing or dry-etching. By way of another example, in the discussed embodiment the active layer 15 was doped with phosphorus by thermal diffusion. Alternatively, dopant can be introduced into the active layer by ion injection. By way of another example, in the discussed embodiment the active layer 15 was doped with phosphorus. Alternatively, other dopants can be used, such as boron, so long as the dopant serves to regulating stress in the active layer. By way of another example, in the discussed embodiment the dopant impurity was introduced (for the purpose of stress regulation) after the SOI wafer 16 and support substrate 12 were bonded together. Alternatively, the impurity can be introduced into the SOI wafer before the bonding step.

Whereas the invention has been described in the context of multiple representative embodiments, the invention is not limited to those embodiments. On the contrary, the invention is intended to encompass all modifications, alternatives, and equivalents as may be included within the spirit and scope of the invention, as defined by the appended claims.

What is claimed is:

1. A reticle blank for making a divided reticle used in charged-particle-beam microlithography, the reticle blank comprising:
a membrane; and
a support substrate defining a grillage of support struts that support the membrane and divide the membrane into subfields, the support substrate having a thickness of at least 1 mm.

2. The reticle blank of claim 1, wherein the support substrate is silicon having a thickness of 1 to 5 mm.

3. The reticle blank of claim 1, wherein the membrane is silicon that has been doped with an impurity to regulate stress in the membrane.

4. A reticle for use in charged-particle-beam microlithography, comprising:
a reticle membrane defining elements of a pattern; and
a support substrate defining a grillage of support struts that support the membrane and divide the membrane into subfields, the support substrate having a thickness of at least 1 mm.

5. The reticle blank of claim 4, wherein the support substrate is silicon having a thickness of 1 to 5 mm.

6. The reticle of claim 4, wherein the membrane is silicon that has been doped with an impurity to regulate stress in the membrane.

7. A method for manufacturing a reticle blank for making a divided reticle used in charged-particle-beam microlithography, the method comprising:
preparing a silicon support substrate having a thickness of at least 1 mm;
working the support substrate to form therein a grillage of support struts defining voids in the support substrate corresponding to locations of respective subfields in the reticle blank;
constructing an SOI wafer comprising an active layer, a buried oxide layer, and a support-wafer layer;
bonding a major surface of the active layer of the SOI wafer to a major surface of the support substrate; and
removing the support-wafer layer and the buried oxide layer to form the reticle blank having a membrane, made from the active layer, divided into subfields supported by the grillage of support struts.

8. The method of claim 7, wherein the silicon support substrate is prepared having a thickness of 1 to 5 mm.

9. The method of claim 7, further comprising the step, after removing the buried oxide layer, of introducing an impurity into the active layer for use in stress reduction of the active layer.

10. The method of claim 7, further comprising the step, between the step of preparing the SOI wafer and the bonding step, of introducing an impurity into the active layer for use in stress reduction of the active layer.

11. The method of claim 7, wherein the working step is performed by anisotropic working.

12. The method of claim 7, wherein the working step is performed by a technique selected from the group consisting of ultrasonic working, plasma-discharge machining, or laser machining.

13. A method for manufacturing a reticle blank for making a divided reticle used in charged-particle-beam microlithography, the method comprising:
preparing a silicon support substrate having a thickness of at least 1 mm;
working the support substrate to form therein a grillage of support struts defining voids in the support substrate corresponding to locations of respective subfields in the reticle blank;
constructing an SOI wafer comprising an active layer, a buried oxide layer, and a support-wafer layer;
forming an oxide film on a major surface of the active layer;
bonding the oxide film on the active layer to a major surface of the support substrate; and
removing the support-wafer layer and the buried oxide layer to form the reticle blank having a membrane, made from the active layer, divided into subfields supported by the grillage of support struts.

14. The method of claim 13, wherein the silicon support substrate is prepared having a thickness of 1 to 5 mm.

15. The method of claim 13, further comprising the step, after removing the buried oxide layer, of introducing an impurity into the active layer for use in stress reduction of the active layer.

16. The method of claim 13, further comprising the step, between the step of preparing the SOI wafer and the bonding step, of introducing an impurity into the active layer for use in stress reduction of the active layer.

17. The method of claim 13, wherein the working step is performed by anisotropic working.

18. The method of claim 13, wherein the working step is performed by a technique selected from the group consisting of ultrasonic working, plasma-discharge machining, or laser machining.

19. A method for manufacturing a reticle blank for making a divided reticle used in charged-particle-beam microlithography, the method comprising:
preparing a silicon support substrate having a thickness of at least 1 mm;
working the support substrate to form therein a grillage of support struts defining voids in the support substrate corresponding to locations of respective subfields in the reticle blank;
forming an oxide film on a major surface of the support substrate;
constructing an SOI wafer comprising an active layer, a buried oxide layer, and a support-wafer layer;
bonding a major surface of the active layer to the oxide film; and
removing the support-wafer layer and the buried oxide layer to form the reticle blank having a membrane, made from the active layer, divided into subfields supported by the grillage of support struts.

20. The method of claim 19, wherein the silicon support substrate is prepared having a thickness of 1 to 5 mm.

21. The method of claim 19, further comprising the step, after removing the buried oxide layer, of introducing an impurity into the active layer for use in stress reduction of the active layer.

22. The method of claim 19, further comprising the step, between the step of preparing the SOI wafer and the bonding step, of introducing an impurity into the active layer for use in stress reduction of the active layer.

23. The method of claim 19, wherein the working step is performed by anisotropic working.

24. The method of claim 19, wherein the working step is performed by a technique selected from the group consisting of ultrasonic working, plasma-discharge machining, or laser machining.

25. A method for manufacturing a reticle blank for making a divided reticle used in charged-particle-beam microlithography, the method comprising:
preparing a silicon support substrate having a thickness of at least 1 mm;
working the support substrate to form therein a grillage of support struts defining voids in the support substrate corresponding to locations of respective subfields in the reticle blank;
preparing a bonding substrate comprising a thin-film silicon layer; and
bonding a major surface of the thin-film silicon layer to a major surface of the support substrate.

26. The method of claim 25, wherein the silicon support substrate is prepared having a thickness of 1 to 5 mm.

27. The method of claim 25, further comprising the step, after the bonding step, of introducing an impurity into the thin-film silicon layer for use in stress reduction of said layer.

28. The method of claim 25, wherein the working step is performed by anisotropic working.

29. The method of claim 25, wherein the working step is performed by a technique selected from the group consisting of ultrasonic working, plasma-discharge machining, or laser machining.

30. A method for manufacturing a reticle for use in charged-particle-beam microlithography, comprising:
preparing a reticle blank by the method recited in claim 7; and
forming elements of a pattern on or in the membrane of the reticle blank.

31. A method for manufacturing a reticle for use in charged-particle-beam microlithography, comprising:
preparing a reticle blank by the method recited in claim 13; and
forming elements of a pattern on or in the membrane of the reticle blank.

32. A method for manufacturing a reticle for use in charged-particle-beam microlithography, comprising:
preparing a reticle blank by the method recited in claim 19; and
forming elements of a pattern on or in the membrane of the reticle blank.

33. A method for manufacturing a reticle for use in charged-particle-beam microlithography, comprising:
preparing a reticle blank by the method recited in claim 25; and
forming elements of a pattern on or in the membrane of the reticle blank.

34. A reticle blank, manufactured by the method recited in claim 7.

35. A reticle blank, manufactured by the method recited in claim 13.

36. A reticle blank, manufactured by the method recited in claim 19.

37. A reticle blank, manufactured by the method recited in claim 25.

38. A divided reticle, manufactured by the method recited in claim 30.

39. A divided reticle, manufactured by the method recited in claim 31.

40. A divided reticle, manufactured by the method recited in claim 32.

41. A divided reticle, manufactured by the method recited in claim 33.
